(19) United States
(12) Patent Application Publication
(10) Pub. No.: US 2024/0276666 A1
(43) Pub. Date: Aug. 15, 2024

(54) TOP-MOUNT PRINTED CIRCUIT BOARD MOUNTING ASSEMBLIES AND ELECTRONIC DEVICES THEREOF

(71) Applicant: Molex, LLC, Lisle, IL (US)

(72) Inventors: Glenn Lee, Fremont, CA (US); Lily Yu Zhuang, San Jose, CA (US)

(21) Appl. No.: 18/424,863

(22) Filed: Jan. 28, 2024

Related U.S. Application Data
(60) Provisional application No. 63/445,006, filed on Feb. 13, 2023.

(51) Int. Cl. H05K 7/14

(52) U.S. Cl. CPC H05K 7/1407

(57) ABSTRACT

Top-mount PCB mounting assemblies, and electronic devices and optical communication device thereof are provided. The top-mount PCB mounting assemblies may include a PCB with a top surface as a reference surface; a chassis disposed underneath the PCB and separate from the PCB; a shoulder screw comprising a screw head, a screw body and a screw tail, where the shoulder screw is soldered on a top of the PCB and is connected to the chassis by tightening a M2.5 screw from a bottom of the chassis; and a nut, positioned between the PCB and the chassis, made of a rigid feature, and configured to receive and fasten the shoulder screw and keep a distance between the PCB and the chassis within a controlled dimension.

### CROSS-REFERENCE TO RELATED APPLICATION

This application claims the benefit of U.S. Provisional Patent Application No. 63/445,006, filed Feb. 13, 2023, and entitled “TOP-MOUNT PRINTED CIRCUIT BOARD (PCB) MOUNTING ASSEMBLIES AND ELECTRONIC DEVICES THEREOF,” which is incorporated by reference herein in its entirety.

### TECHNICAL FIELD

This disclosure is related to printed circuit board (PCB) mounting assemblies. More specifically, this disclosure relates to top-mount PCB mounting assemblies, and electronic devices and optical communication devices using the same.

### BACKGROUND

In mounting hardware, linecards need to be inserted into a chassis, and the backplane connectors between the chassis and the linecard need to be aligned to avoid damage. There are tolerances that need to be taken into consideration. In most designs, the bottom of the PCB in linecard is used as the reference surface to complete the tolerance analysis and to ensure the design will function properly and will not incur damage upon insertion.

Additionally, the linecard needs to pass mechanical shock and vibration testing. The mounting hardware needs to take this into account, since energy from shock and vibration can be transmitted to the linecard, causing unintended performance changes.

### SUMMARY

Examples of the present disclosure provide top-mount PCB mounting assemblies, electronic devices and optical communication devices with the top-mount PCB mounting assemblies.

According to a first aspect of the present disclosure, a top-mount PCB mounting assembly is provided. The top-mount PCB mounting assembly may include: a PCB with a top surface as a reference surface; a chassis disposed underneath the PCB and separate from the PCB; a shoulder screw comprising a screw head, a screw body and a screw tail, where the shoulder screw is soldered on a top of the PCB and is connected to the chassis by tightening a screw from a bottom of the chassis; and a nut, positioned between the PCB and the chassis, made of a rigid feature, and configured to receive and fasten the shoulder screw and keep a distance between the PCB and the chassis within a controlled dimension.

According to a second aspect of the present disclosure, an electronic device is provided. The electronic device may include a top-mount PCB mounting assembly as disclosed in the first aspect of the present disclosure.

According to a third aspect of the present disclosure, an optical communication device is provided. The optical communication device may include at least one linecard that includes a top-mount PCB mounting assembly as disclosed in the first aspect of the present disclosure.

It is to be understood that the above general descriptions and detailed descriptions below are only exemplary and explanatory and not intended to limit the present disclosure.

### BRIEF DESCRIPTION OF THE DRAWINGS

The accompanying drawings, which are incorporated in and constitute a part of this specification, illustrate examples consistent with the present disclosure and, together with the description, serve to explain the principles of the disclosure.

FIG. 1 illustrates a side view of the top-mount PCB mounting assembly in accordance with some implementations of the present disclosure.

FIG. 2 illustrates a partial side view of the top-mount PCB mounting assembly in accordance with some implementations of the present disclosure.

FIG. 3 illustrates a side view of the top-mount PCB mounting assembly in accordance with some implementations of the present disclosure.

FIG. 4 illustrates a perspective view of a nut of the top-mount PCB mounting assembly in accordance with some implementations of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the disclosure as recited in the appended claims.

Terms used in the present disclosure are merely for describing specific examples and are not intended to limit the present disclosure. The singular forms “one”, “the”, and “this” used in the present disclosure and the appended claims are also intended to include a multiple form, unless other meanings are clearly represented in the context. It should also be understood that the term “and/or” used in the present disclosure refers to any or all of possible combinations including one or more associated listed items.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

It should be understood that although terms “first”, “second”, “third”, and the like are used in the present disclosure to describe various information, the information is not limited to the terms. These terms are merely used to differentiate information of a same type. For example, without departing from the scope of the present disclosure, first information is also referred to as second information, and similarly the second information is also referred to as the first information. Depending on the context, for example, the term “if” used herein may be explained as “when” or “while”, or “in response to . . . , it is determined that”.

In some existing designs, it may be difficult to assemble the hardware structure of the PCB, due to the combination of spring, washer and the bottom mount in the PCB assembly. It requires access to both the top and bottom of the unit at the same time to construct the assembly. It is also difficult for quality control in production. The relatively complex working procedure cannot guarantee the assembly meets the required specification. The overall height of the PCB assembly also cannot be well controlled due to the floating structure, which leads to potential back plane connector damages. Besides, in some designs with the spring, the springs may cause shock and vibration issues, and create resonant frequencies.

In the present disclosure, a top-mounting PCB mounting assembly is presented. The design of the mounting hardware uses the top of the PCB as the reference surface, and has two implementations to ensure proper alignment. In one implementation, a solid mounting method is utilized, and in another implementation, a spring is used to ensure proper alignment. The spring mechanism can help suppress and dampen mechanical vibration energy to the linecard.

Examples of the top-mounting PCB mounting assembly in accordance with the present disclosure use the top of the PCB as the reference surface to locate the linecard within the carrier. Such top-down assembly may also be more efficient in manufacturing, since it does not necessarily require access to both the top and bottom of the unit at the same time to construct the assembly. In some of the examples of the top-mounting PCB mounting assembly, a spring may be used, and in some other examples, a spacer may be used for rigid mount, where the spacer is a solid part and the boards are rigidly mounted to the chassis.

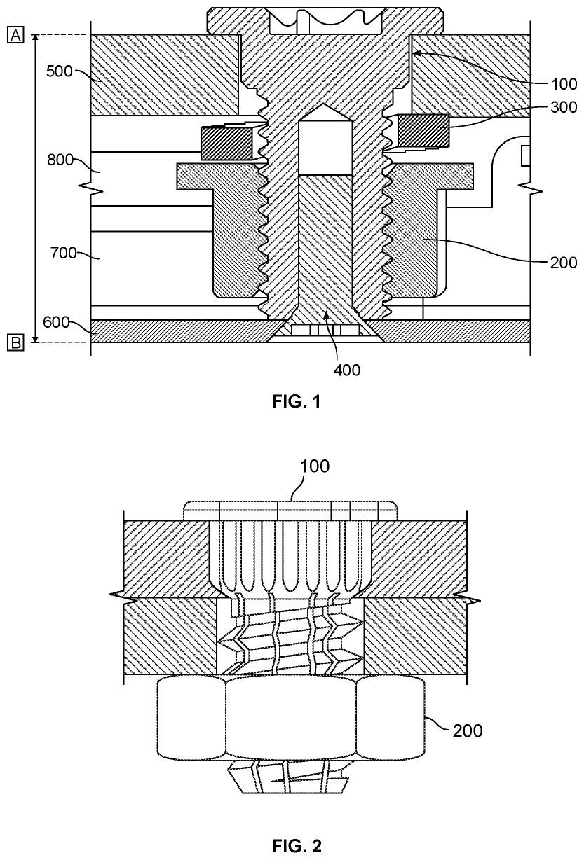

FIG. 1 illustrates an example of the top-mount PCB mounting assembly in accordance with the present disclosure. In one or more examples, the PCB mounting assembly may include a shoulder screw 100, a nut 200, a spring washer 300, a screw 400, a PCB 500, a chassis 600, and multiple structural layers 700, 800. The PCB 500 is on the top of the assembly structure, and the chassis 600 is at the bottom of the assembly structure. Multiple other structural layers 700, 800 may be disposed in between the PCB 500. The PCB 500, the structural layers 800, 700 and the chassis 600 are assembled, from top to bottom, by the shoulder strew 100, the nut 200, the spring washer 300 and the screw 400. In one example, the screw 400 may be a M2.5 screw and the screw size is not limited to this example.

The top surface of the PCB 500 may serve as a reference surface, for example as shown in FIG. 1, reference surface A. The bottom surface of the chassis 600 may serve as bottom reference surface B, as shown in FIG. 1. In such top-mounting PCB assembly, the maximum height between the reference surface A and the reference surface B is about 10.50+/−0.10 mm. In one or more examples, the height between the reference surface A and the reference surface B is in the range of 5.0 mm to 11.0 mm, or more preferably in the range of 8.0 mm to 10.5 mm. In some other examples, the height between the reference surface A and the reference surface B may be different. Such top-down assembly design may be easier for installation and helpful to ensure proper alignment.

In one example of the top-mounting PCB mounting assembly, a spring washer 300 is provided in between the shoulder screw 100 and the nut 200. The spring washer 300 is in contact with the bottom surface of the PCB 500 and a top surface of the nut 200. The spring washer 300 is about in a circular shape and is screwed around the threaded joint of the screw shoulder 100. The spring washer 300 may add tension to the threaded joint of the shoulder screw 100, in order to prevent the assembly from loosening by small amounts of vibration. The spring washer 300 may also help to suppress and dampen mechanical vibration energy to the linecard.

In some examples, a M2.5 screw 400 is provided in the top-mounting PCB mounting assembly. The M2.5 screw 400 may be inserted from the bottom of the chassis 600 into a hollow part of the shoulder screw 100. The M2.5 screw is fastened into the shoulder screw 100 and may provide additional stability in the mounting assembly to ensure proper alignment. The M2.5 screw is an example of the screw that may be used to fasten into the shoulder screw. Screws of other diameter sizes may also be applied here based on the shoulder screw sizes and the general needs of the PCB mounting assembly.

In some examples, the shoulder screw 100 may be fixed on the top surface of the PCB 300. The shoulder screw may be soldered onto the top surface of the PCB 300.

FIG. 2 is a partial side view of the top-mount PCB mounting assembly, and illustrates part of a shoulder screw 100 and a nut 200 around a PCB 500 according to one example of the disclosure. In this example, no spring washer is provided between the shoulder screw 100 and the nut 200. The nut 200 is fastened onto the shoulder screw 100. The top surface of the nut 200 is in direct contact with a bottom surface of the PCB 500. The top surface of the nut may be threaded in some examples, so that it may provide additional friction to prevent relative rotation between the contact of the nut 200 and the PCB 500.

In some examples, a rubber O-ring may be used in replacement of a nut 200. Such rubber O-ring is fastened onto the shoulder screw 100, and the rubber O-ring is in direct contact with the bottom surface of the PCB 500.

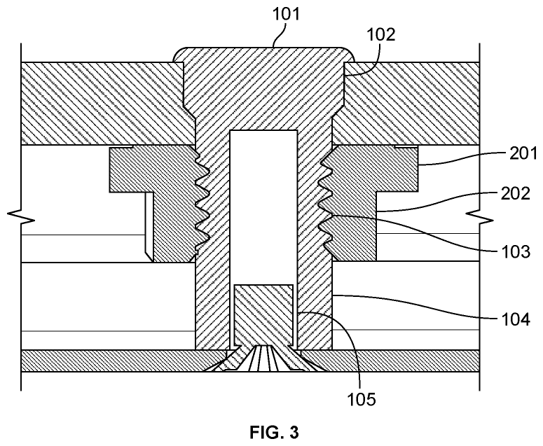

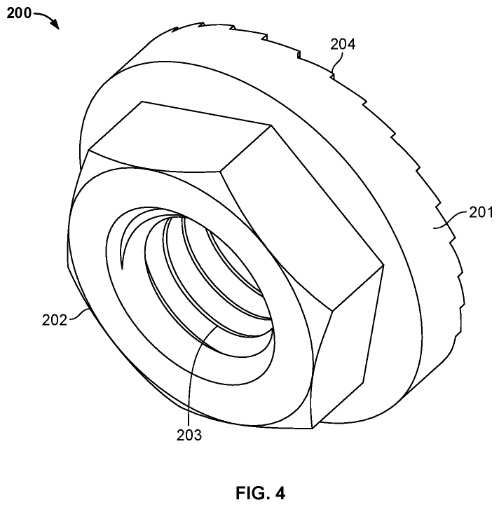

FIG. 3 illustrates another example of the top-mount PCB mounting assembly in accordance with the present disclosure. The shoulder screw 100 includes a screw head 101, a screw body 102, 103, and a screw tail 104. The screw head 101 includes a top flat surface and may be parallel to the PCB and other structural layers in the mounting assembly. In some examples, the screw head 101 may be soldered on the top surface of the PCB 500.

The screw body may include a first screw body part 102 and a second screw body part 103. The first screw body part 102 is connected with the screw head 101, and the first screw body part 102 penetrates through the PCB 500 in the mounting assembly. The side of the first screw body part 102 may be straight in some examples, or the side of the first screw body part 102 may include a step slope in some other examples. Longitudinal threads along the length of the shoulder screw 100 may also be included around the side surface of the first screw body part 102. Such threads may be helpful for increasing the friction at the contact between the PCB 500 and the first screw body part 102, so that relative rotations may be reduced in the mounting assembly. In some examples, the first screw body part 102 may also be soldered to the PCB to ensure the proper alignment of the mounting assembly.

The second screw body part 103 are provided in between the first screw body part 102 and the screw tail 104. There are spiral threads around the outer surface of the second screw body part 103. The spiral threads are provided to fasten the nut 200 between the PCB and the chassis. In the mounting assembly, the second screw body part is generally between the PCB 500 and some other structural layers.

The screw tail 104 is connected with the second screw body part 103 and penetrates through other structural layers in the mounting assembly. The bottom end surface of the screw tail 104 may contact the inner/upper surface of the chassis and/or sit on top of the chassis in some examples of the mounting assembly. In some examples, the screw tail 104 may be fixed in the chassis.

The shoulder screw 100 may also be hollow inside in some examples, such as the core part of the second screw body 103 and the screw tail 104 is hollow. The hollow part 105 of the shoulder screw 100 is provided to accommodate and fasten a M2.5 screw 400. The M2.5 screw is inserted from a bottom surface of the chassis, and the M2.5 screw tightens the mounting assembly from the bottom side of the chassis. The M2.5 screw is an example of the screw that may be used to fasten into the shoulder screw. Screws of other diameter sizes may also be applied here based on the shoulder screw sizes and the general needs of the PCB mounting assembly.

FIG. 4 illustrates a perspective view of a nut 200 of the top-mount PCB mounting assembly in accordance with some examples of the present disclosure. In some examples, the nut 200 may include a nut head 201 and a nut tail 202. The top surface of the nut head 202 may be in direct contact with a bottom surface of the PCB 500 or with a spring washer 300. The nut tail 202 is connected with the nut head 201, and the nut tail may sit on or fixed into other structural layers of the mounting assembly. In some examples, the cross-sectional area of the nut head 201 is bigger than the cross-sectional area of the nut tail 202.

The core of the nut 200 is hollow to be fastened onto the shoulder screw 100. The inner surface 203 of the circumferential side wall of the nut 200 includes spiral threads, and such spiral threads are configured to fasten onto the spiral threads of the second screw body part 103 of the shoulder screw 100.

In some examples, the top surface 204 of the nut 200 may be in direct contact with the bottom surface of the PCB 500 in the mounting assembly. The top surface 204 of the nut 200 may also include threads to prevent further rotation between the PCB 500 and the nut 200 in the mounting assembly. In some other examples where a spring washer 300 is provided between the nut 200 and the PCB 500, the spring washer 300 is disposed between the top surface 204 of the nut head 200 and the bottom surface of the PCB 500 to prevent additional rotation between the PCB and the nut.

In accordance with the present disclosure, an electronic device may also be provided. The electronic device may include the top-mounted PCB mounting assembly as described above. The electronic device may include the top-mount PCB mounting assembly, which may include a PCB with a top surface as a reference surface; a chassis disposed underneath the PCB and separate from the PCB; a shoulder screw comprising a screw head, a screw body and a screw tail, wherein the shoulder screw is soldered on a top of the PCB and is connected to the chassis by tightening a M2.5 screw from a bottom of the chassis; and a nut, positioned between the PCB and the chassis, made of a rigid feature, such as sheet metal, and configured to receive and fasten the shoulder screw and keep a distance between the PCB and the chassis within a controlled dimension.

In some examples of the electronic device, the screw body may also include a first screw body part connected with the screw head and a second screw body part connected with the screw tail; the first screw body part may penetrate through the PCB and may include an external thread extended along a length direction of the screw body to fix the PCB from rotating relatively to the shoulder screw. The second screw body part may include a first spiral thread around an outer surface of the second screw body to fasten the nut between the PCB and the chassis. An inner surface of a circumferential side wall of the nut may include a second spiral thread configured to accommodate the shoulder screw by fastening on the first spiral thread of the second screw body part.

In some examples of the electronic device, the screw head of the shoulder screw may be attached onto the top surface of the PCB, and the screw tail is fixed in the chassis. The nut may include a nut head and a nut tail, a cross-sectional area of the nut head is bigger than a cross-sectional area of the nut tail. The top surface of the nut head may be in contact with a bottom surface of the PCB in the top-mount PCB mounting assembly, and the top surface of the nut head may be threaded to prevent further rotation between the PCB and the nut; or a spring washer may be disposed between the top surface of the nut head and the bottom surface of the PCB to prevent rotation between the PCB and the nut.

In some other examples of the present disclosure, an optical communication device is also provided. The optical communication device may include at least one linecard, and the linecard may include a PCB with a top surface as a reference surface; a chassis disposed underneath the PCB and separate from the PCB; a shoulder screw comprising a screw head, a screw body and a screw tail, wherein the shoulder screw is soldered on a top of the PCB and is connected to the chassis by tightening a M2.5 screw from a bottom of the chassis; and a nut, positioned between the PCB and the chassis, made of a rigid feature, and configured to receive and fasten the shoulder screw and keep a distance between the PCB and the chassis within a controlled dimension.

The description of the present disclosure has been presented for purposes of illustration and is not intended to be exhaustive or limited to the present disclosure. Many modifications, variations, and alternative implementations will be apparent to those of ordinary skill in the art having the benefit of the teachings presented in the foregoing descriptions and the associated drawings.

Unless specifically stated otherwise, an order of steps of the method according to the present disclosure is only intended to be illustrative, and the steps of the method according to the present disclosure are not limited to the order specifically described above, but may be changed according to practical conditions. In addition, at least one of the steps of the method according to the present disclosure may be adjusted, combined or deleted according to practical requirements.

The examples were chosen and described in order to explain the principles of the disclosure and to enable others skilled in the art to understand the disclosure for various implementations and to best utilize the underlying principles and various implementations with various modifications as are suited to the particular use contemplated. Therefore, it is to be understood that the scope of the disclosure is not to be limited to the specific examples of the implementations disclosed and that modifications and other implementations are intended to be included within the scope of the present disclosure.

What is claimed is:

1. A top-mount printed circuit board (PCB) mounting assembly, comprising:
a PCB with a top surface as a reference surface;
a chassis disposed underneath the PCB and separate from the PCB;
a shoulder screw comprising a screw head, a screw body and a screw tail, wherein the shoulder screw is soldered on a top of the PCB and is connected to the chassis by tightening a screw from a bottom of the chassis; and
a nut, positioned between the PCB and the chassis, made of a rigid feature, and configured to receive and fasten the shoulder screw and keep a distance between the PCB and the chassis within a controlled dimension.

2. The top-mount PCB mounting assembly of claim 1, wherein the screw body comprises a first screw body part connected with the screw head and a second screw body part connected with the screw tail.

3. The top-mount PCB mounting assembly of claim 2, wherein the first screw body part penetrates through the PCB and comprises an external thread extended along a length direction of the screw body to fix the PCB from rotating relatively to the shoulder screw.

4. The top-mount PCB mounting assembly of claim 2, wherein the first screw body part penetrates through the PCB and is soldered to the PCB.

5. The top-mount PCB mounting assembly of claim 2, wherein the second screw body part comprises a first spiral thread around an outer surface of the second screw body to fasten the nut between the PCB and the chassis.

6. The top-mount PCB mounting assembly of claim 5, wherein an inner surface of a circumferential side wall of the nut comprises a second spiral thread configured to accommodate the shoulder screw by fastening on the first spiral thread of the second screw body part.

7. The top-mount PCB mounting assembly of claim 1, wherein in the top-mount PCB mounting assembly, the screw head of the shoulder screw is attached onto the top surface of the PCB, and the screw tail is fixed in the chassis.

8. The top-mount PCB mounting assembly of claim 1, wherein the nut comprises a nut head and a nut tail, a cross-sectional area of the nut head is bigger than a cross-sectional area of the nut tail.

9. The top-mount PCB mounting assembly of claim 8, wherein a top surface of the nut head is in contact with a bottom surface of the PCB in the top-mount PCB mounting assembly, and the top surface of the nut head is threaded to prevent further rotation between the PCB and the nut; or
wherein a spring washer is disposed between the top surface of the nut head and the bottom surface of the PCB to prevent rotation between the PCB and the nut.

10. An electronic device, comprising:
a top-mount printed circuit board (PCB) mounting assembly that comprises:
a PCB with a top surface as a reference surface;
a chassis disposed underneath the PCB and separate from the PCB;
a shoulder screw comprising a screw head, a screw body and a screw tail, wherein the shoulder screw is soldered on a top of the PCB and is connected to the chassis by tightening a screw from a bottom of the chassis; and
a nut, positioned between the PCB and the chassis, made of a rigid feature, and configured to receive and fasten the shoulder screw and keep a distance between the PCB and the chassis within a controlled dimension.

11. The electronic device of claim 10, wherein the screw body comprises a first screw body part connected with the screw head and a second screw body part connected with the screw tail.

12. The electronic device of claim 11, wherein the first screw body part penetrates through the PCB and comprises an external thread extended along a length direction of the screw body to fix the PCB from rotating relatively to the shoulder screw.

13. The electronic device of claim 11, wherein the first screw body part penetrates through the PCB and is soldered to the PCB.

14. The electronic device of claim 11, wherein the second screw body part comprises a first spiral thread around an outer surface of the second screw body to fasten the nut between the PCB and the chassis.

15. The electronic device of claim 14, wherein an inner surface of a circumferential side wall of the nut comprises a second spiral thread configured to accommodate the shoulder screw by fastening on the first spiral thread of the second screw body part.

16. The electronic device of claim 10, wherein in the top-mount PCB mounting assembly, the screw head of the shoulder screw is attached onto the top surface of the PCB, and the screw tail is fixed in the chassis.

17. The electronic device of claim 10, wherein the nut comprises a nut head and a nut tail, a cross-sectional area of the nut head is bigger than a cross-sectional area of the nut tail.

18. The electronic device of claim 17, wherein a top surface of the nut head is in contact with a bottom surface of the PCB in the top-mount PCB mounting assembly, and the top surface of the nut head is threaded to prevent further rotation between the PCB and the nut; or
wherein a spring washer is disposed between the top surface of the nut head and the bottom surface of the PCB to prevent rotation between the PCB and the nut.

19. An optical communication device, comprising:
at least one linecard that comprises:
a PCB with a top surface as a reference surface;
a chassis disposed underneath the PCB and separate from the PCB;
a shoulder screw comprising a screw head, a screw body and a screw tail, wherein the shoulder screw is soldered on a top of the PCB and is connected to the chassis by tightening a screw from a bottom of the chassis; and
a nut, positioned between the PCB and the chassis, made of a rigid feature, and configured to receive and fasten the shoulder screw and keep a distance between the PCB and the chassis within a controlled dimension.

20. The optical communication of claim 19, wherein the screw body comprises a first screw body part connected with the screw head and a second screw body part connected with the screw tail.
